(19) United States
(12) Patent Application Publication
(10) Pub. No.: US 2009/0180262 A1
(43) Pub. Date: Jul. 16, 2009

(54) Inverter

(75) Inventors: Hannes Knopf, Kassel (DE); Frank Lampe, Guxhagen (DE)

Correspondence Address: PYLE & PIONTEK, LLC, 221 N LASALLE STREET , ROOM 1207, CHICAGO, IL, 60601, US

(73) Assignee: SMA Solar Technology AG, Niestetal (DE)

(21) Appl. No.: 12/315,021

(22) Filed: Nov. 25, 2008

(30) Foreign Application Priority Data
Jan. 11, 2008 (DE) 202008000440.0

(51) Int. Cl. H05K 1/18

(52) U.S. Cl. 361/748

(57) ABSTRACT

The invention is directed to an inverter with a board for receiving electric and electronic component parts by arranging at least one DIN rail relay onto the board (5) of the inverter.

### FIELD OF THE INVENTION

The invention relates to an inverter with a board for accommodating electric and electronic components.

Inverters are well known; inverters more specifically serve as PV inverters for converting solar direct current voltage into an alternating current voltage at mains frequency for feeding into a utility grid. The voltage may hereby be provided by a PV generator, but also by a battery.

Inverters, in particular for installing on small surfaces, are generally characterized by a compact construction so that they can be mounted readily and at little expense. As already explained, the electric and electronic components are accommodated in the housing of the inverter. The higher the output of the apparatus, meaning of the inverter, the larger the component parts. Moreover, inverters for feeding into the utility grid are subject to specific requirements. This more specifically relates to safety regulations which include inter alia the disconnection from the grid of a PV plant including the generator and the inverter. Relays are hereby used, such relays being mounted onto DIN rails, the connection to the corresponding plugs of the board or printed circuit board then occurring through cables. The DIN rail for accommodating the relays is disposed in a switching cabinet.

In any case the problem is that mounting additionally the relays onto the DIN rails (DIN rail relays) involves particular expense and what is much more important, the current-carrying capacity of this relays strongly depends on the quality of the cable connection. Since such cable connections are made manually, they are quite prone to failure which finally results in low current carrying capacity in the event of a poor electrical connection. This means that the object of the invention is not only to reduce the expense in mounting such type DIN relays but also to improve the quality of the electrical connection between relay and printed circuit board.

### BRIEF SUMMARY OF THE INVENTION

In accordance with the invention, this object is achieved by arranging at least one DIN rail relay on the board of the inverter. For this purpose, the DIN rail possesses load terminals and driver terminals, said terminals comprising webs projecting through corresponding holes in the board in order to solder them to the board. The advantage of this design is obvious: through the automated connection of the relay to the printed circuit board or the board, human errors, which may occur when manually connecting the cable like in prior art, are avoided. Moreover, the mounting expense is lower since the DIN relays need no longer be wired together with the printed circuit board in the switching cabinet on the site during mounting of the inverter.

The invention is also directed to using a DIN relay as a relay for disconnecting the electric generator and/or the inverter from the grid to equip the board of the inverter with components. Such a DIN rail relay is particularly suited for this purpose since it can be utilized for current intensities of more than 30 A whilst having a small overall size. Except for such DIN rail relays, other relays or contactors to be soldered on a board of the same overall size for similar current intensities are not commercially available.

The invention will be described in closer detail herein after with reference to the drawings.

### BRIEF DESCRIPTION OF THE DRAWINGS

FIG. 1 shows the relays in a perspective bottom view of the DIN rail relay;

FIG. 2 and FIG. 3 schematically shows an outline of the board with a DIN rail relay seated thereon, each in another view.

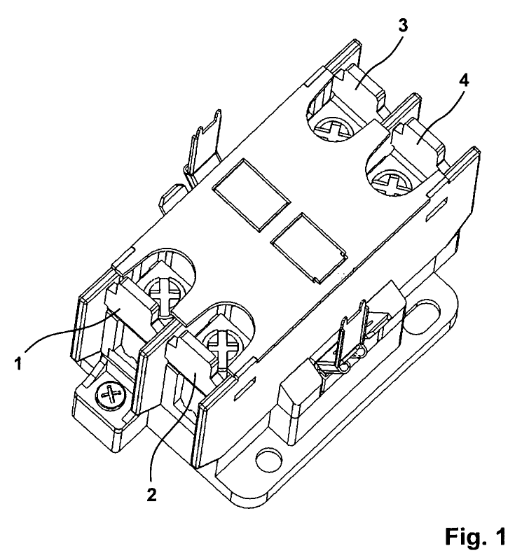

### DETAILED DESCRIPTION OF THE INVENTION

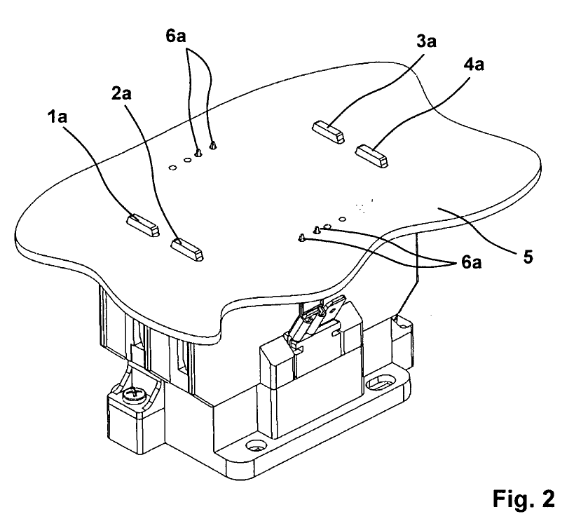

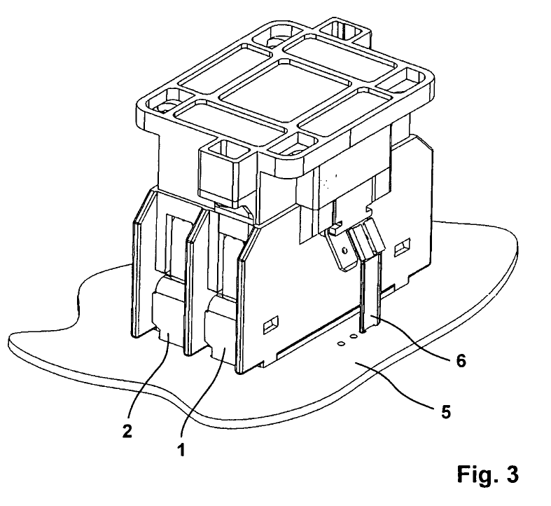

The structure of a DIN rail relay is known. The present relay respectively has on two opposite sides two load terminals 1, 2, 3, 4. These load terminals contain webs 1a, 2a, 3a, 4a that project through the board 5 as can be seen from FIG. 2 and from FIG. 3. Moreover, so-called control terminals 6 are provided, the webs 6a of which also project through the board 5. The substance-to-substance bond of the webs both with respect to the load terminals and to the control terminals occurs mechanically by what is referred to as wave soldering.

We claim:

1. An inverter with a board for receiving electric and electronic component parts,
characterized by arranging at least one DIN rail relay on the board (5) of the inverter.

2. The inverter as set forth in claim 1, characterized in that the DIN rail relay comprises load terminals (1, 2, 3, 4) and driver terminals (6), said terminals comprising webs (1a, 2a, 3a, 4a; 6a) projecting through corresponding holes in the board (5) in order to be soldered to the board (5).

3. Use of a DIN rail relay as a relay for disconnecting the electric generator and/or the inverter from the grid in order to mount component parts onto the board of the inverter.
